(19) United States
(12) Patent Application Publication
(10) Pub. No.: US 2023/0245943 A1
(43) Pub. Date: Aug. 3, 2023

(54) SEMICONDUCTOR MODULE

(71) Applicant: HONDA MOTOR CO., LTD., Tokyo (JP)

(72) Inventor: Kazuhisa Ishizuka, Wako-shi (JP)

(21) Appl. No.: 18/158,814

(22) Filed: Jan. 24, 2023

(30) Foreign Application Priority Data
Jan. 28, 2022 (JP) 2022-011430

(51) Int. Cl. H01L 23/367; H01L 23/528

(52) U.S. Cl. CPC H01L 23/367; H01L 23/5283

(57) ABSTRACT

A semiconductor module includes a semiconductor element, a first heat dissipation portion, and a spacer. A connection area of the spacer where the spacer contacts the first heat dissipation portion is larger than a connection area of the spacer where the spacer contacts the semiconductor element. Heat of the semiconductor element is dissipated from the first heat dissipation portion via the spacer.

### CROSS-REFERENCE TO RELATED APPLICATIONS

This application is based upon and claims the benefit of priority from Japanese Patent Application No. 2022-011430 filed on Jan. 28, 2022, the contents of which are incorporated herein by reference.

### BACKGROUND OF THE INVENTION

### Field of the Invention

The present invention relates to a semiconductor module.

### Description of the Related Art

JP 2009-188346 A discloses a semiconductor module having a plurality of semiconductor elements, spacers, and two heat dissipation plates. Each of the semiconductor elements is connected to one of the heat dissipation plates via a spacer. Each of the semiconductor elements is directly connected to the other heat dissipation plate. The heat of each semiconductor element is dissipated from one heat dissipation plate via the spacer and from the other heat dissipation plate.

### SUMMARY OF THE INVENTION

If a connection area of the spacer where the spacer and the semiconductor element are connected were increased, the heat dissipation performance of the semiconductor element would be improved. However, a signal line for externally controlling the semiconductor element is connected to the semiconductor element. If the connection area between the spacer and the semiconductor element were increased, the spacer would interfere with the signal line and a connecting portion (pad portion) of the semiconductor element where the signal line is connected to the semiconductor element.

Further, a guard ring is formed at the outer peripheral portion of the semiconductor element in order to mitigate electric field concentration at the PN junction of the semiconductor. If the spacer is a conductor, it is necessary to avoid contact between the spacer and the guard ring.

Thus, the size of the spacer is limited because of interference with the signal line and electrical insulation from the guard ring.

An object of the present invention is to solve the aforementioned problem.

A semiconductor module includes a semiconductor element, a heat dissipation portion, and a spacer that is provided between the semiconductor element and the heat dissipation portion, wherein heat of the semiconductor element is dissipated from the heat dissipation portion via the spacer, and a connection area of the spacer where the spacer contacts the heat dissipation portion is larger than a connection area of the spacer where the spacer contacts the semiconductor element.

According to the present invention, the heat dissipation performance of the semiconductor element can be improved even when the size of the spacer is limited. Further, a space for connecting the semiconductor element and the signal line can be easily acquired.

The above and other objects, features, and advantages of the present invention will become more apparent from the following description when taken in conjunction with the accompanying drawings, in which a preferred embodiment of the present invention is shown by way of illustrative example.

### BRIEF DESCRIPTION OF THE DRAWINGS

FIG. 1 is a circuit diagram of an electric power conversion apparatus provided with a semiconductor module according to an embodiment.

FIG. 2 is a perspective view of the semiconductor module.

FIG. 3 is a partial plan view of the semiconductor module.

FIG. 4 is a sectional view taken along a line IV-IV of FIG. 3.

### DETAILED DESCRIPTION OF THE INVENTION

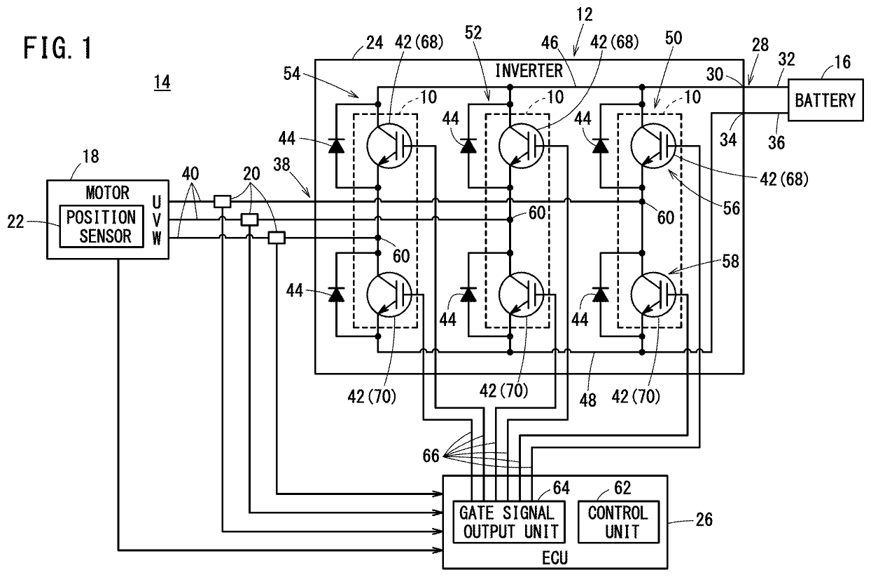

FIG. 1 is a circuit diagram of an electric power conversion apparatus 12 provided with a semiconductor module 10 according to an embodiment. The electric power conversion apparatus 12 is mounted, for example, on a vehicle 14.

The vehicle 14 includes the electric power conversion apparatus 12, a battery 16, a motor 18, a plurality of current sensors 20, and a position sensor 22. The motor 18 is a three phase (U-phase, V-phase, and W-phase) AC motor. The position sensor 22 is provided at the motor 18. The power conversion apparatus 12 includes an inverter 24 and an ECU (electronic control unit) 26.

An input side 28 of the inverter 24 is electrically connected to the battery 16. Specifically, a positive terminal 30 on the input side 28 of the inverter 24 and a positive terminal of the battery 16 are electrically connected via a positive power line 32. Further, a negative terminal 34 of the input side 28 of the inverter 24 and a negative terminal of the battery 16 are electrically connected via a negative power line 36.

An output side 38 of the inverter 24 is electrically connected to the motor 18. Specifically, the output side 38 of the inverter 24 and the motor 18 are electrically connected via three output lines 40. Each of the three output lines 40 is provided with a current sensor 20.

The inverter 24 has a configuration of a three phase bridge circuit corresponding to the three phase motor 18. Specifically, the inverter 24 has six switching elements 42 and six diodes 44. Each switching element 42 is a semiconductor device such as an IGBT (Insulated Gate Bipolar Transistor). In FIG. 1, the switching element 42 is an N-channel type IGBT.

In the inverter 24, a positive power line 46 is connected to the positive terminal 30. A negative power line 48 is connected to the negative terminal 34. The negative power line 48 is a ground line.

The inverter 24 has three phase arms 50 to 54. The three phase arms 50 to 54 are electrically connected to the positive power line 46 and the negative power line 48. The three phase arms 50 to 54 are connected in parallel with respect to the input side 28 of the inverter 24. In the following description, the phase arm 50 corresponding to the U-phase of the motor 18 is referred to as a U-phase arm 50. The phase arm 52 corresponding to the V-phase of the motor 18 is referred to as a V-phase arm 52. The phase arm 54 corresponding to the W-phase of the motor 18 is referred to as a W-phase arm 54.

The U-phase arm 50, the V-phase arm 52, and the W-phase arm 54 each have an upper arm 56 and a lower arm 58. The upper arm 56 and the lower arm 58 are electrically connected to the positive power line 46 and the negative power line 48. The upper arm 56 and the lower arm 58 are connected in series between the positive power line 46 and the negative power line 48. Specifically, one end of the upper arm 56 is connected to the positive power line 46. The other end of the upper arm 56 is connected to one end of the lower arm 58. The other end of the lower arm 58 is connected to the negative power line 48.

For each of the U-phase arm 50, the V-phase arm 52, and the W-phase arm 54, a connection point 60 at which the other end of the upper arm 56 is connected to one end of the lower arm 58 is a midpoint of each of the phase arms 50 to 54. A U-phase output line 40 is connected to the connection point 60 of the U-phase arm 50. A V-phase output line 40 is connected to the connection point 60 of the V-phase arm 52. A W-phase output line 40 is connected to the connection point 60 of the W-phase arm 54.

Each of the upper arm 56 and the lower arm 58 has a switching element 42 and a diode 44. The switching element 42 and the diode 44 are connected in parallel to each of the upper arm 56 and the lower arm 58.

Specifically, as for the upper arm 56, the cathode of the diode 44 and the collector of the switching element 42 are connected to the positive power line 46. Further, as for the upper arm 56, the anode of the diode 44 and the emitter of the switching element 42 are connected to the connection point 60.

As for the lower arm 58, the cathode of the diode 44 and the collector of the switching element 42 are connected to the connection point 60. Further, as for the lower arm 58, the anode of the diode 44 and the emitter of the switching element 42 are connected to the negative power line 48.

The ECU 26 includes a control unit 62 and a gate signal output unit 64. The ECU 26 controls each part of the vehicle 14. The gate signal output unit 64 is electrically connected to the gates of the six switching elements 42 via six signal supply lines 66.

Each of the U-phase arm 50, the V-phase arm 52, and W-phase arm 54 has the semiconductor module 10. The semiconductor module 10 includes the switching element 42 of the upper arm 56 and the switching element 42 of the lower arm 58. In the following description, the switching element 42 of the upper arm 56 is referred to as a first switching element 68. The switching element 42 of the lower arm 58 is referred to as a second switching element 70.

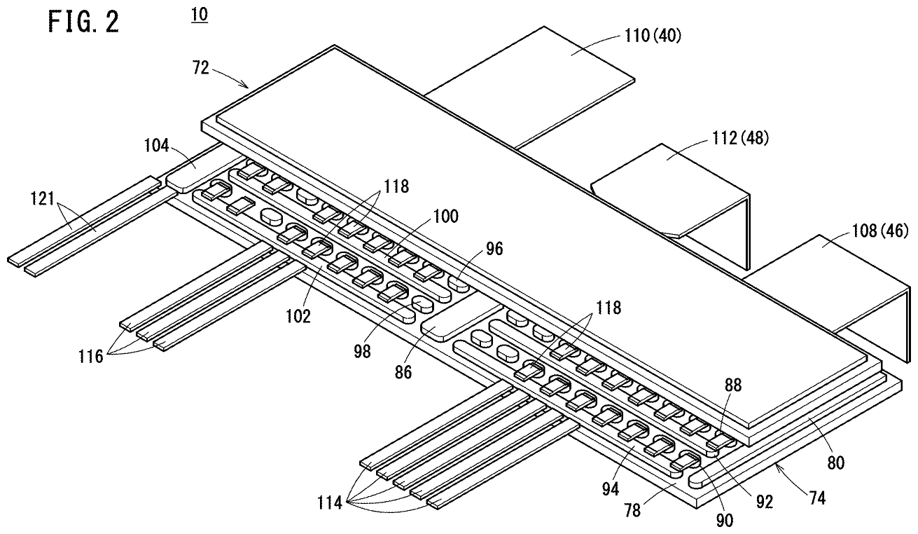

Next, the structure of the semiconductor module 10 will be described with reference to FIGS. 2 to 4. Each semiconductor module 10 of the U-phase arm 50, the V-phase arm 52, and the W-phase arm 54 has the same configuration. Therefore, the semiconductor module 10 of the U-phase arm 50 will be representatively described with reference to FIGS. 2 to 4.

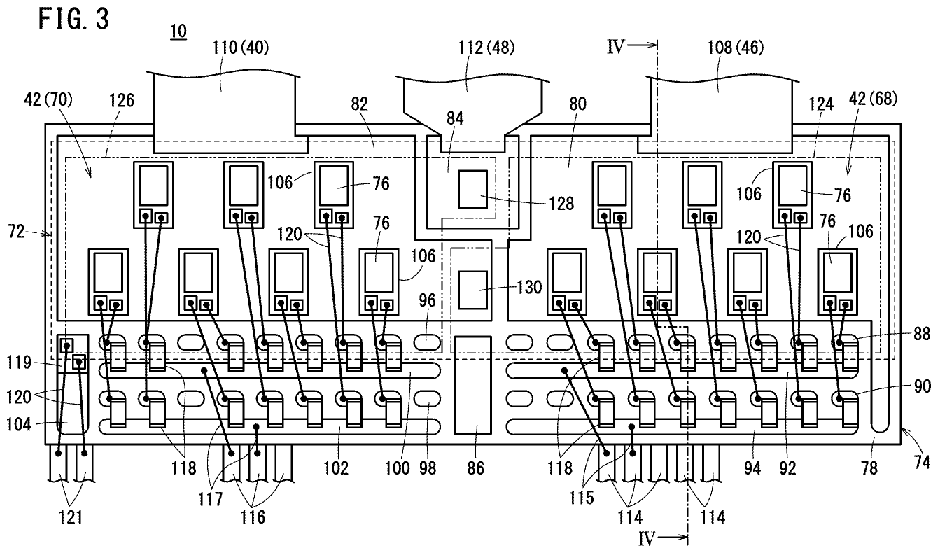

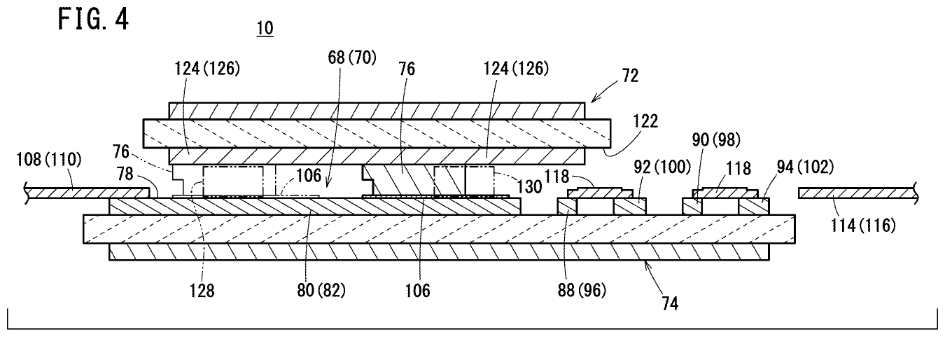

FIG. 2 is a perspective view of the semiconductor module 10. FIG. 3 is a partial plan view of the semiconductor module 10. FIG. 4 is a sectional view taken along a line IV-IV of FIG. 3.

The semiconductor module 10 includes the first switching element 68, the second switching element 70, a first heat dissipation portion 72 (heat dissipation portion), a second heat dissipation portion 74, and a plurality of spacers 76.

The first heat dissipation portion 72 and the second heat dissipation portion 74 are plate-shaped heat dissipation substrates. Each of the first heat dissipation portion 72 and the second heat dissipation portion 74 is a stacked substrate in which a conductive layer and an electrically insulating layer are stacked alternately. In FIGS. 2 to 4, the first heat dissipation portion 72 and the second heat dissipation portion 74 have been deformed into a three layer substrate for convenience of explanation.

As shown in FIG. 4, the first switching element 68 and the second switching element 70 are provided so as to be sandwiched between the first heat dissipation portion 72 and the second heat dissipation portion 74. A plurality of spacers 76 are provided between the first heat dissipation portion 72 and the first switching element 68 and between the first heat dissipation portion 72 and the second switching element 70. The first switching element 68 and the second switching element 70 are connected to the first heat dissipation portion 72 via a plurality of spacers 76. The plurality of spacers 76 are electrically conductive. Further, the first switching element 68 and the second switching element 70 are connected to the second heat dissipation portion 74.

The first heat dissipation portion 72 and the plurality of spacers 76 are connected to each other via solder (not shown). The plurality of spacers 76 are connected to the first switching element 68 and the second switching element 70 via solder (not shown). The first switching element 68 and the second switching element 70 are connected to the second heat dissipation portion 74 via solder (not shown).

As shown in FIG. 3, a plurality of conductive portions 80 to 104 are formed on a surface 78 of the second heat dissipation portion 74, the surface 78 facing the first heat dissipation portion 72. For convenience of explanation, the surface 78 of the second heat dissipation portion 74 is referred to as an upper surface 78. In FIG. 3, the second heat dissipation portion 74 is shown by broken lines. Further, the conductive portions 80 to 104 are spaced apart from each other at arbitrary intervals on the upper surface 78.

In FIG. 3, the conductive portions 80 and 82 having relatively large areas are formed on both the left and right sides of the upper surface 78 of the second heat dissipation portion 74. The two conductive portions 80 and 82 are conductive patterns formed on the upper surface 78 of the second heat dissipation portion 74. The first switching element 68 is disposed in the right conductive portion 80. The second switching element 70 is disposed in the left conductive portion 82.

Each of the first switching element 68 and the second switching element 70 is made up from a plurality of semiconductor elements 106. FIG. 3 shows a case where each of the first switching element 68 and the second switching element 70 is made up from seven semiconductor elements 106. Each of the plurality of semiconductor elements 106 is a plate-shaped semiconductor element (see FIG. 4).

Each of the plurality of semiconductor elements 106 is connected to the spacer 76 via solder. The plurality of semiconductor elements 106 are arranged on the surfaces of the left and right conductive portions 80 and 82. Specifically, each of the seven semiconductor elements 106 constituting the first switching element 68 is connected to the right conductive portion 80 via solder. Each of the seven semiconductor elements 106 constituting the second switching element 70 is connected to the left conductive portion 82 via solder.

As described later, each of the plurality of semiconductor elements 106 turns on and off based on a gate signal supplied from the gate signal output unit 64 (see FIG. 1).

A positive terminal 108 is connected to the right conductive portion 80. The positive terminal 108 is a bus bar. The positive terminal 108 is part of the positive power line 46 (see FIG. 1). An output terminal 110 is connected to the left conductive portion 82. The output terminal 110 is a bus bar. The output terminal 110 is part of the U-phase output line 40.

A conductive portion 84 is formed between the left and right conductive portions 80, 82 on the upper surface 78 of the second heat dissipation portion 74. The conductive portion 84 is a rectangular conductive pattern. A negative terminal 112 is connected to the conductive portion 84. The negative terminal 112 is a bus bar. The negative terminal 112 is part of the negative power line 48 (see FIG. 1).

A conductive portion 86 is formed at a central portion in the left-right direction of the upper surface 78 of the second heat dissipation portion 74. The conductive portion 86 is a rectangular conductive pattern. A plurality of rows of conductive portions 88, 90, 96, 98 and a plurality of conductive portions 92, 94, 100, 102 are formed on the upper surface 78 of the second heat dissipation portion 74 so as to sandwich the rectangular conductive portion 86.

On the right side of the upper surface 78 of the second heat dissipation portion 74, rows of the plurality of conductive portions 88 and 90 and the conductive portions 92 and 94 are alternately arranged so as to be close to the conductive portion 80. In FIG. 3, two rows of the plurality of conductive portions 88 and 90 and two of the conductive portions 92 and 94 are alternately arranged on the right side of the upper surface 78 of the second heat dissipation portion 74. The plurality of conductive portions 88 and 90 are elliptic conductive patterns. The plurality of conductive portions 88 and 90 are relatively small-area conductive patterns. The plurality of conductive portions 92 and 94 are rod-shaped conductive patterns. The plurality of conductive portions 92 and 94 are conductive patterns having substantially the same length as the rows of the plurality of conductive portions 88 and 90.

Five signal terminals 114 are arranged at the second heat dissipation portion 74 so as to be close to the conductive portions 88 to 94. Among the five signal terminals 114, two signal terminals 114 are electrically connected to the rows of the conductive portions 88 and 90, respectively. Specifically, one signal terminal 114 of the two signal terminals 114 is electrically connected to the plurality of conductive portions 88. The other signal terminal 114 of the two signal terminals 114 is electrically connected to the plurality of conductive portions 90.

Other two signal terminals 114 of the five signal terminals 114 are electrically connected to the conductive portions 92 and 94, respectively. Specifically, one signal terminal 114 of the two signal terminals 114 is electrically connected to the conductive portion 92 via a signal line 115 such as a bonding wire. The other signal terminal 114 of the two signal terminals 114 is electrically connected to the conductive portion 94 via another signal line 115.

On the left side of the upper surface 78 of the second heat dissipation portion 74, rows of the plurality of conductive portions 96 and 98 and the conductive portions 100 and 102 are alternately arranged so as to be close to the conductive portion 82. In FIG. 3, two rows of the plurality of conductive portions 96 and 98 and two of the conductive portions 100 and 102 are alternately arranged on the left side of the upper surface 78 of the second heat dissipation portion 74. The plurality of conductive portions 96 and 98 are elliptical conductive patterns. The plurality of conductive portions 96, 98 are relatively small-area conductive patterns. The plurality of conductive portions 100 and 102 are rod-shaped conductive patterns. The plurality of conductive portions 100 and 102 are conductive patterns having substantially the same length as the rows of the plurality of conductive portions 96 and 98.

Three signal terminals 116 are arranged at the second heat dissipation portion 74 so as to be close to the conductive portions 96 to 102. One signal terminal 116 of the three signal terminals 116 is electrically connected to one row of the conductive portions 96 and 98. The other row of conductive portions 96 and 98 is electrically connected to, for example, one signal terminal 114. The remaining two signal terminals 116 are electrically connected to the conductive portions 100 and 102 via signal lines 117 such as bonding wires.

A plurality of chip resistors 118 are disposed between the plurality of conductive portions 88, 90, 96, 98 and the plurality of conductive portions 92, 94, 100, 102. Each of the plurality of chip resistors 118 is arranged so as to connect one conductive portion 88, 90, 96, 98 and one conductive portion 92, 94, 100, 102. That is, one end of the chip resistor 118 is electrically connected to one conductive portion 88, 90, 96, 98. The other end of the chip resistor 118 is electrically connected to one conductive portion 92, 94, 100, 102.

Fourteen chip resistors 118 are arranged on the right side of the upper surface 78 of the second heat dissipation portion 74. That is, the number of the chip resistors 118 on the right side is twice as many as the number of the semiconductor elements 106 constituting the first switching element 68. Fourteen chip resistors 118 are arranged on the left side of the upper surface 78 of the second heat dissipation portion 74. That is, the number of the chip resistors 118 on the left side is twice as many as the number of the semiconductor elements 106 constituting the second switching element 70.

One conductive portion 88, 90, 96, 98 to which one end of the chip resistor 118 is connected is electrically connected to one semiconductor element 106 via a signal line 120 such as a bonding wire. One semiconductor element 106 is electrically connected to two conductive portions 88, 90, 96, 98 via two signal lines 120.

The plurality of signal lines 120 and the plurality of signal terminals 114 and 116 constitute part of the plurality of signal supply lines 66. In this case, each of the conductive portions 92, 94, 100, and 102 becomes a conductive pattern having a reference potential (for example, zero potential) for the gate signal. The signal potential of the gate signal is supplied to each of the conductive portions 88, 90, 96 and 98. That is, each of the conductive portions 88, 90, 96 and 98 is supplied with a signal potential (high level or low level gate signal) based on the reference potential.

A conductive portion 104 is formed on the left side of the upper surface 78 of the second heat dissipation portion 74. The conductive portion 104 is a rectangular conductive pattern. The conductive portion 104 is provided with a temperature sensor 119. Two output terminals 121 are arranged at the second heat dissipation portion 74 so as to be close to the conductive portion 104. Each of the two output terminals 121 is electrically connected to the temperature sensor 119 via a signal line 120.

As shown in FIGS. 3 and 4, two conductive portions 124 and 126 are formed on a surface 122 of the first heat dissipation portion 72, the surface 122 facing the second heat dissipation portion 74. For convenience of explanation, the surface 122 of the first heat dissipation portion 72 is referred to as a bottom surface 122.

On the right side of the bottom surface 122 of the first heat dissipation portion 72, the conductive portion 124 is formed so as to face the first switching element 68. The conductive portion 124 is a plate-shaped conductive pattern. The conductive portion 124 is formed on the bottom surface 122 of the first heat dissipation portion 72 so as to cover the seven semiconductor elements 106, the seven spacers 76, and part of the conductive portion 82.

On the left side of the bottom surface 122 of the first heat dissipation portion 72, the conductive portion 126 is formed so as to face the second switching element 70. The conductive portion 126 is a plate-shaped conductive pattern. The conductive portion 126 is formed on the bottom surface 122 of the first heat dissipation portion 72 so as to cover the seven semiconductor elements 106, the seven spacers 76, and part of the conductive portion 84.

Each of the plurality of spacers 76 connects the semiconductor element 106 and the conductive portions 124 and 126 facing the semiconductor element 106. As described above, each semiconductor element 106 is plate-shaped. The conductive portions 124 and 126 are formed on the bottom surface 122 of the plated-shaped first heat dissipation portion 72. Therefore, each of the plurality of spacers 76 is in surface-contact with the upper surface (surface) of the semiconductor element 106. Each of the plurality of spacers 76 is in surface-contact with the conductive portions 124 and 126. As described above, each of the plurality of spacers 76 is joined to the upper surface of the semiconductor element 106 via solder. Each of the plurality of spacers 76 is joined to the conductive portions 124 and 126 via solder.

Moreover, a contact area (connection area) of each of the plurality of spacers 76 where the spacers 76 contact the conductive portions 124 and 126 is larger than a contact area (connection area) of each of the spacers where the spacers contact the upper surface of the semiconductor element 106. Specifically, the cross-sectional area of the spacer 76 increases toward the first heat dissipation portion 72. More specifically, the cross-sectional area of the spacer 76 increases in a stepwise manner toward the first heat dissipation portion 72. In FIG. 4, the cross-sectional area of the spacer 76 increases in the form of two steps toward the first heat dissipation portion 72.

In this case, the signal line 120 electrically connects the semiconductor element 106 and the conductive portions 88, 90, 96, 98, avoiding the first heat dissipation portion 72 and the spacer 76.

A connecting portion 128 is disposed on the surface of the conductive portion 84. The connecting portion 128 is electrically conductive. The connecting portion 128 connects the conductive portion 84 and the conductive portion 126 formed on the left side of the bottom surface 122 of the first heat dissipation portion 72.

A connecting portion 130 is disposed on the surface of the conductive portion 82. The connecting portion 130 is electrically conductive. The connecting portion 130 connects the conductive portion 82 and the conductive portion 124 formed on the right side of the bottom surface 122 of the first heat dissipation portion 72.

Here, the correspondence between the circuit diagram of FIG. 1 and FIGS. 2 to 4 will be described.

The positive terminal 108 and the conductive portion 80 correspond to a connecting portion between the collector of the first switching element 68 and the positive power line 46. The conductive portion 124, the connecting portion 130, and the conductive portion 82 of the second heat dissipation portion 74 correspond to the connection point 60 of the U-phase. Each spacer 76 on the right side corresponds to a connecting portion between the connection point 60 and the emitter of the first switching element 68.

The conductive portion 82 corresponds to a connecting portion between the collector of the second switching element 70 and the connection point 60. The left spacers 76, the left conductive portion 126 of the first heat dissipation portion 72, the connecting portion 128, and the conductive portion 84 correspond to a connecting portion between the emitter of the second switching element 70 and the negative power line 48.

In the above description of FIGS. 2 to 4, the semiconductor module 10 of the U-phase arm 50 has been described. In the above description, if the term related to “U-phase” is replaced with “V-phase”, the description becomes the one for the semiconductor module 10 of the V-phase arm 52. In the above description, if the term related to “U-phase” is replaced with “W-phase”, the description becomes the one for the semiconductor module 10 of the W-phase arm 54.

The operation of the power conversion apparatus 12 including the semiconductor module 10 configured as described above will be described with reference to FIGS. 1 to 4.

The control unit 62 (see FIG. 1) of the ECU 26 sets a target value for the output of the motor 18. The control unit 62 instructs the gate signal output unit 64 to output a gate signal corresponding to the set target value. The gate signal output unit 64 generates the gate signal corresponding to the target value based on the instruction from the control unit 62. The gate signal output unit 64 outputs the generated gate signal to each switching element 42 (the first switching element 68 and the second switching element 70) via each signal supply line 66.

In each switching element 42, each semiconductor element 106 (see FIG. 3) is turned on/off based on gate signals supplied via the signal terminal 114 and the signal line 120. In this way, the inverter 24 can convert the DC power supplied from the battery 16 into three phase AC power. The converted AC power is output to the motor 18 via the three output lines 40. The motor 18 is driven by a rotor (not shown) rotated based on the supplied AC power.

When the motor 18 functions as a generator, the motor 18 outputs the generated AC power to the inverter 24 via the three output lines 40. At the inverter 24, each semiconductor element 106 turns on and off based on the gate signal, whereby the three phase AC power can be converted into DC power. The converted DC power is output to the battery 16 via the positive power lines 32 and 46 and the negative power lines 36 and 48. In this way, the battery 16 is charged.

When each semiconductor element 106 is driven in this manner, heat is generated at each semiconductor element 106. Part of the heat of each semiconductor element 106 is transmitted to the first heat dissipation portion 72 via the spacer 76. That is, the spacer 76 is a heat transfer path for each semiconductor element 106. The first heat dissipation portion 72 dissipates heat transferred from each spacer 76 to the outside. Further, another part of the heat of each semiconductor element 106 is transmitted to the second heat dissipation portion 74. The second heat dissipation portion 74 dissipates heat transferred from each semiconductor element 106 to the outside.

The temperature sensor 119 (see FIG. 3) detects the temperature of the semiconductor module 10 and outputs a result of the detection to the ECU 26. Each current sensor 20 detects AC current flowing through the output line 40 and outputs a result of the detection to the ECU 26. The position sensor 22 detects a rotational position of the rotor constituting the motor 18 and outputs a result of the detection to the ECU 26.

The control unit 62 of the ECU 26 can perform feedback control with respect to the target value by setting a target value in consideration of the detection results having been input or the like.

In the present embodiment, the cross-sectional area of the spacer 76 may continuously increase toward the first heat dissipation portion 72. Specifically, the spacer 76 may have a trapezoidal shape in cross section.

Further, in this embodiment, the spacer 76 may be disposed for each signal line 120 or each terminal (positive terminal 108, output terminals 110 and 121, negative terminal 112, signal terminals 114 and 116).

Further, in the present embodiment, the number of semiconductor elements 106 constituting the switching element 42 can be arbitrarily set. In this case, the number of chip resistors 118 will be changed in accordance with the number of semiconductor elements 106.

The invention that can be understood from the above embodiments will be described below.

A semiconductor module (10) includes a semiconductor element (106), a heat dissipation portion (72), and a spacer (76) that is provided between the semiconductor element and the heat dissipation portion, wherein heat of the semiconductor element is dissipated from the heat dissipation portion via the spacer, and a connection area of the spacer where the spacer contacts the heat dissipation portion is larger than a connection area of the spacer where the spacer contacts the semiconductor element.

According to the present invention, the heat dissipation performance of the semiconductor element can be improved even when the size of the spacer is limited. Further, a space for connecting the semiconductor element and the signal line can be easily acquired.

In an aspect of the present invention, a cross-sectional area of the spacer may increase toward the heat dissipation portion.

Thus, the heat dissipation performance of the semiconductor element can be improved while a space for the signal lines is acquired.

In an aspect of the present invention, a cross-sectional area of the spacer may increase in a stepwise manner toward the heat dissipation portion.

Thus, the spacer can be easily formed.

In an aspect of the present invention, the spacer may be in surface-contact with the surface of the semiconductor element and the heat dissipation portion.

As a result, the heat of the semiconductor element is efficiently transmitted to the heat dissipation portion through the spacer. As a result, the heat dissipation performance of the semiconductor can be further improved.

In an embodiment of the present invention, the spacer may be electrically conductive.

Thus, the heat dissipation performance of the semiconductor can be further improved. In addition, the spacer serving as a heat transfer path can be used as a power transfer path.

The present invention is not limited to the above-described disclosure and various configurations can be adopted without departing from the gist of the present invention.

1. A semiconductor module comprising:
a semiconductor element;
a heat dissipation portion; and
a spacer that is provided between the semiconductor element and the heat dissipation portion,
wherein
heat of the semiconductor element is dissipated from the heat dissipation portion via the spacer, and
a connection area of the spacer where the spacer contacts the heat dissipation portion is larger than a connection area of the spacer where the spacer contacts the semiconductor element.

2. The semiconductor module according to claim 1,
wherein
a cross-sectional area of the spacer increases toward the heat dissipation portion.

3. The semiconductor module according to claim 2,
wherein
a cross-sectional area of the spacer increases in a stepwise manner toward the heat dissipation portion.

4. The semiconductor module according to claim 1,
wherein
the spacer is in surface-contact with a surface of the semiconductor element and the heat dissipation portion.

5. The semiconductor module according to claim 1,
wherein
the spacer is electrically conductive.
